(19) United States
(12) Patent Application Publication
(10) Pub. No.: US 2012/0121818 A1
(43) Pub. Date: May 17, 2012

(54) COATING SURFACE PROCESSING METHOD AND COATING SURFACE PROCESSING APPARATUS

(75) Inventors: Shuji Kodaira, Susono-shi (JP); Tomoyuki Yoshihama, Susono-shi (JP); Koukichi Kamada, Susono-shi (JP); Kazumasa Horita, Susono-shi (JP); Junichi Hamaguchi, Susono-shi (JP); Shigeo Nakanishi, Susono-shi (JP); Satoru Toyoda, Susono-shi (JP)

(73) Assignee: ULVAC, INC., Chigasaki-shi (JP)

(21) Appl. No.: 13/386,264

(22) PCT Filed: Jul. 21, 2010
(86) PCT No.: PCT/JP2010/062217

§ 371 Date: Jan. 20, 2012

(30) Foreign Application Priority Data
Jul. 21, 2009 (JP) P2009-170576

(51) Int. Cl. B05D 3/06; B05C 11/00; C23C 14/34

(52) U.S. Cl. 427/535; 204/192.12; 118/620

(57) ABSTRACT

A coating surface processing method includes forming a coating on the entire surface of a base body that has fine holes or fine grooves formed on the to-be-filmed surface, including the inner wall surfaces and the inner bottom surfaces of the holes or the grooves, and flattening the coating formed on the inner wall surfaces of the holes or the grooves by carrying out a plasma processing on the surface of the coating.

### TECHNICAL FIELD

The present invention relates to a coating surface processing method and a coating surface processing apparatus.

Priority is claimed on Japanese Patent Application No. 2009-170576, filed Jul. 21, 2009, the content of which is incorporated herein by reference.

### BACKGROUND ART

In multilayer wiring techniques that are essential for manufacturing semiconductor elements, such as an LSI, the sputtering method plays a vital role as a method for forming thin film wires.

In a vacuum chamber in an ordinary sputtering apparatus used for the sputtering method, a target composed of a wire material is provided so that the target faces a base body, which is an object on which a film is formed, with a predetermined gap therebetween. A magnetic field is formed on the surface of the target using a magnetic circuit in which a permanent magnet and the like provided on the rear surface of the target outside the vacuum chamber are used, and a negative voltage is applied to the target; therefore, plasma of sputtering gas, such as argon (Ar), that is introduced to the vacuum chamber is generated in the vicinity of the target, ionized sputtering gas ions are injected to the target, the wire material is emitted from the surface of the target, and is attached on the surface of the base body, thereby forming a coating composed of the wire material.

Generally, the diameter of a silicon wafer, which is the base body, is increased, or the wires are micronized in order to increase the manufacturing efficiency and performance of LSI chips and the like, and, recently, a silicon wafer having a diameter of 300 mm has been used. In a case in which a coating composed of the wire material is formed on a large-diameter base body having fine holes and grooves by the sputtering method, there is a demand for an advanced technique in order to uniformly coat the fine holes or the fine grooves which act as wires provided on the base body. For example, the ratio of the depth to entrance diameter of the fine hole or the fine groove is termed an aspect ratio, and the coating thickness at the inner bottom surface of the fine hole or the fine groove having a high aspect ratio tends to become thinner than the coating thickness at the surface of the base body. That is, there is a tendency for the bottom coverage (the ratio of the coating thickness at the inner bottom surface of the fine hole or the fine groove to the coating thickness at the surface of the base body) to decrease. Similarly, there is a tendency for the side coverage (the ratio of the coating thickness at the inner wall surface of the fine hole or the fine groove to the coating thickness at the surface of the base body) to decrease.

One of the causes of the above tendencies is that sputtering particles, which are composed of the wire material and blown out from the target, collide with the sputtering gas in the vacuum chamber so as to be scattered while travelling to the surface of the base body, and the fraction of the sputtering particles that are vertically injected to the base body is decreased. The sputtering particles, which are injected to the base body from an inclined direction, fail to reach the inside of the fine holes or the fine grooves having a high aspect ratio, and are deposited at the opening end portions of the fine holes or the fine grooves. Therefore, in order to enable a larger number of the sputtering particles to reach the inside of the fine holes or the fine grooves having a high aspect ratio, a method is disclosed in which the degree of vacuum in the vacuum chamber is controlled before and after generation of the plasma, whereby the degree of scattering of sputtered copper particles is suppressed (Patent Document 1).

### PRIOR ART DOCUMENT

### Patent Document

[Patent Document 1] Japanese Unexamined Patent Application, First Publication No. 2004-6942

### SUMMARY OF INVENTION

### Problems to be Solved by the Invention

When the base body is viewed from the plasma generated in the vicinity of the target, there are inner wall surfaces on the inner side of the fine holes or the fine grooves provided on the base body (the central side of the base body) which become shadowed areas, the coating efficiency at these areas is generally low, and there is a problem in that minute protrusions and recesses are liable to be generated on the surface of the formed coating. Since particularly large areas become shadowed in the fine holes or the fine grooves provided on the end portion side of the base body compared with the fine holes or the fine grooves provided at the central portion of the base body, the extent of the minute protrusions and recesses generated on the coating surface is also increased. Since the minute protrusions and recesses on the coating surface affect the performance of the wires formed in the fine holes or the fine grooves, and also may cause degradation of the wires, the coating surface is desirably flat.

The object of aspects according to the invention is to provide a coating surface processing method and a coating surface processing apparatus which can flatten minute protrusions and recesses on the surface of a coating formed on the inner wall surfaces of fine holes or fine grooves formed in a base body.

### Means for Solving the Problem

A coating surface processing method of an aspect according to the invention includes forming a coating on an entire surface of a base body, the base body having fine holes or fine grooves formed on a to-be-filmed surface thereof and the entire surface including inner wall surfaces and inner bottom surfaces of the holes or the grooves of the base body, and then flattening the coating formed on the inner wall surfaces of the holes or the grooves by carrying out a plasma processing on the surface of the coating.

In the coating surface processing method, the coating is formed on the base body by the sputtering method.

In the coating surface processing method, during the sputtering method, a vacuum chamber in which the target is disposed so as to face the base body is used, first plasma is generated at a location near the target when the coating is formed on the base body, and second plasma is generated at a location near the base body when the coating is flattened.

In the coating surface processing method, the second plasma is distributed so that the plasma processing is carried out on the entire areas of the coating formed on the base body.

In the coating surface processing method, in a case in which a direct current power applied to the target is indicated by Cp(A) when the coating is formed on the base body, a direct current power applied to the target is indicated by Cp(B) when the coating is flattened, a gas pressure at which the plasma is generated is indicated by P(A) when the coating is formed on the base body, a gas pressure at which the plasma is generated is indicated by P(B) when the coating is flattened, a high-frequency power applied to the base body is indicated by Sp(A) when the coating is formed on the base body, and a high-frequency power applied to the base body is indicated by Sp(B) when the coating is flattened, the following formulae (1), (2), and (3) are satisfied.

Cp(A)>Cp(B) (1)

P(A)<P(B) (2)

Sp(A)<Sp(B) (3)

The coating surface processing apparatus of an aspect according to the invention employs the above coating surface processing method.

### Advantage of the Invention

According to the coating surface processing method and the coating surface processing apparatus of the aspects according to the invention, the surfaces of coatings formed on the inner wall surfaces of the fine holes or the fine grooves in the base body can be flattened.

### BRIEF DESCRIPTION OF THE DRAWINGS

FIG. 1 shows an example of a sputtering apparatus that can employ the coating surface processing method of the aspect according to the invention.

FIG. 2 is a cross-sectional view of a coated fine groove.

FIG. 3A is a cross-sectional view of a coated fine groove after the plasma processing.

FIG. 3B is a cross-sectional view of a coated fine groove after the plasma processing.

FIG. 3C is a cross-sectional view of a coated fine groove after the plasma processing.

### DESCRIPTION OF THE PRESENT EMBODIMENTS

Hereinafter, the aspects according to the invention will be described based on preferred embodiments with reference to the accompanying drawings.

The coating surface processing method of the present embodiment has a process A for forming a coating on the entire surface of a base body that has fine holes or fine grooves formed on the to-be-filmed surface, and includes the inner wall surfaces and the inner bottom surfaces of the holes or the grooves, and a process B for flattening the coating formed on the inner wall surfaces of the holes or the grooves by carrying out a plasma processing on the surface of the coating.

<Process A>

In the process A, well-known film-forming methods can be applied as the method for forming the coating on the entire surface of the base body, and examples thereof which can be applied include PVD methods, such as a sputtering method and vapor deposition; vapor-phase growth methods, such as thermal CVD and plasma CVD; and the like. Among the above film-forming methods, the sputtering method or the plasma CVD method is preferred since the process A and a process B as described below can be advanced in the same film-forming apparatus. In addition, the film-forming method in the process A is more preferably the sputtering method since minute protrusions and recesses are more easily generated particularly on the inner side of the coating formed on the inner wall surfaces of the fine holes or grooves formed on the base body than in a case in which a CVD method is used, and a larger effect of flattening the coating surface in the process B as described below can be obtained.

A material for the base body, which is used in the process A, is not particularly limited as long as the material can endure the film-forming method, and can endure a plasma processing in the process B as described below, and, for example, a substrate for semiconductor elements is preferred. Examples of the substrate material for semiconductor elements include silicon, silicon dioxide (SiO₂), and the like. In a case in which the above substrate is used as the base body in the present embodiment, a coating, such as a metal barrier layer, may be formed on the substrate in advance.

In the base body used in the process A, fine holes or grooves are formed in advance on the to-be-filmed surface. The size of the fine hole or groove may be the size of a fine hole (via hole) or a fine groove (trench) that is formed in an ordinary semiconductor substrate. That is, the opening size of the fine hole or the fine groove is preferably 1.0 nm to 10 μm, more preferably 1.0 nm to 1.0 μm, and still more preferably 1.0 nm to 0.5 μm. When the opening size is within the above range, the effect of the present embodiment can be obtained more sufficiently.

Materials that are used for well-known PVD methods and CVD methods can be applied as the material for the coating formed on the base body, and, for example, a wire material used for wiring of semiconductor elements can be applied. More specific examples thereof include gold (Au), silver (Ag), copper (Cu), palladium (Pd), nickel (Ni), aluminum (Al), chromium (Cr), tantalum (Ta), silicon (Si), and the like, among them, Au, Ag, Cu, and Pd are preferred, and Cu is more preferred since the effect of the present embodiment is excellent.

In a case in which the film-forming method is the sputtering method, the same material as for the coating may be used as the material of the target.

In the process A, the thickness of the coating formed on the inner wall surface of the fine holes or the fine grooves is not particularly limited, and the film thickness may be, for example, 1.0 nm to 1.0 μm. The size of the minute protrusions and recesses that can be formed on the surface of the coating formed into a film thickness within the above range can be approximately 0.5 times to 3 times the coating thickness.

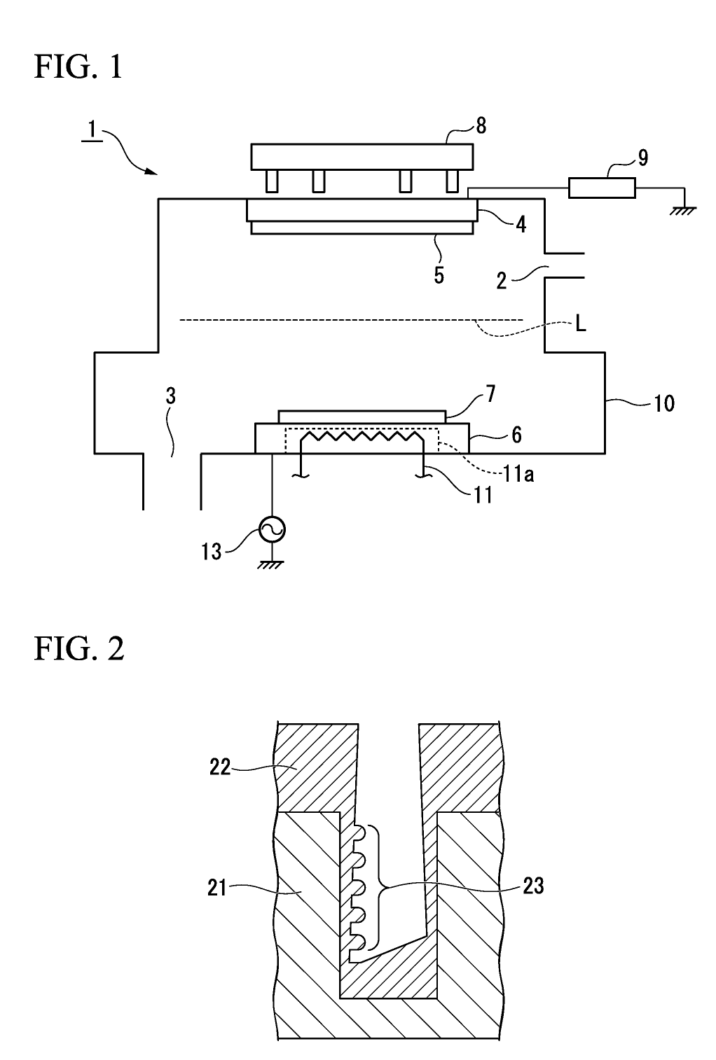

In the process A, an example of a film-forming apparatus that can be used to form the coating on the base body having the fine holes or grooves formed on the to-be-filmed surface is the sputtering apparatus 1 as shown in FIG. 1.

A cathode electrode 4 is fixed to the roof of a vacuum chamber 10 in the sputtering apparatus 1, and a target 5 is disposed on the surface of the cathode electrode. A direct current power supply 9 that applies a negative voltage is connected to the cathode electrode 4.

A magnetic circuit 8 composed of a permanent magnet is provided at the rear surface location of the cathode electrode 4 outside the vacuum chamber 10, and a magnetic flux formed by the magnetic circuit 8 penetrates the cathode electrode 4 and the target 5 so that a leakage magnetic field is formed on the surface of the target 5. When sputtering is carried out, electrons are trapped in the leakage magnetic field, and plasma becomes highly dense.

Discharging is started by applying a negative voltage to the cathode electrode 4, the plasma of an inert gas introduced to the vacuum chamber 10 is generated, sputtering particles are blown out from the target 5, and reach the surface of a base body 7, thereby forming a coating.

A target composed of a well-known material that is used for sputtering may be used as the target 5, and the material is not particularly limited, but a copper target composed of copper is preferred since the effect of the present embodiment can be obtained more sufficiently.

A base body electrode 6 is provided on the bottom surface of the vacuum chamber 10, and the base body 7 is disposed on the surface of the base body electrode substantially in parallel with and opposite to the target 5.

The base body electrode 6 is connected to a high-frequency power supply 13 that applies a high-frequency bias power. In addition, a heater 11, which is electrically insulated by an insulating portion 11a, is provided in the base body electrode 6 so that the temperature of the base body 7 can be adjusted to −50° C. to 600° C.

A gas introduction opening 2 and a vacuum exhaust opening 3 are provided in the vacuum chamber 10. A gas cylinder of an inert gas and the like is connected to the gas introduction opening 2, and a vacuum pump is connected to the vacuum exhaust opening 3 (the gas cylinder and the vacuum pump are not shown).

By a well-known sputtering method in which the sputtering apparatus 1 is used, a coating having a film thickness of 10 nm can be formed on the entire surface of the to-be-filmed surface of the base body, on which fine holes or fine grooves having an opening size of, for example, 50 nm are formed. At this time, a plurality of minute protrusions and recesses having a size of approximately 5 nm can be generated particularly on the inner side of the coating formed on the inner wall surfaces of the fine holes or the fine grooves. The size or generation area of the minute protrusions and recesses can be changed by the film-forming conditions in the sputtering apparatus.

In a case in which the coating is formed on the entire surface of the to-be-filmed surface of the base body 7 using the sputtering apparatus 1, the following film-forming conditions are preferred since a coating that is appropriate for the coating surface processing method of the present embodiment can be efficiently formed.

The direct current power applied to the target 5 (cathode power) is preferably 10 kW to 50 kW, more preferably 10 kW to 35 kW, and still more preferably 10 kW to 20 kW.

The gas pressure at which the plasma is generated (the pressure inside the vacuum chamber 10) is preferably 0.001 Pa to 0.5 Pa, more preferably 0.01 Pa to 0.25 Pa, and still more preferably 0.01 Pa to 0.1 Pa.

The high-frequency power applied to the base body 7 by the high-frequency power supply 13 (stage high-frequency power) is preferably 0 W to 100 W, more preferably 30 W to 80 W, and still more preferably 40 W to 60 W.

The frequency applied to the base body 7 by the high-frequency power supply 13 is preferably 1.0 MHz to 13.56 MHz since a coating that is appropriate for the coating surface processing method of the present embodiment can be efficiently formed.

A preferred combination of the respective ranges of the cathode power, the pressure inside the vacuum chamber 10, and the stage high-frequency power is that the cathode power is in a range of 10 kW to 50 kW, the pressure inside the vacuum chamber 10 is in a range of 0.001 Pa to 0.5 Pa, and the stage high-frequency is in a range of 0 W to 100 W.

A more preferred combination of the respective ranges of the cathode power, the pressure inside the vacuum chamber 10, and the stage high-frequency power is that the cathode power is in a range of 10 kW to 35 kW, the pressure inside the vacuum chamber 10 is in a range of 0.01 Pa to 0.25 Pa, and the stage high-frequency is in a range of 30 W to 80 W.

A still more preferred combination of the respective ranges of the cathode power, the pressure inside the vacuum chamber 10, and the stage high-frequency power is that the cathode power is in a range of 10 kW to 20 kW, the pressure inside the vacuum chamber 10 is in a range of 0.01 Pa to 0.1 Pa, and the stage high-frequency is in a range of 40 W to 60 W.

With the above combination, a coating that is appropriate for the coating surface processing method of the present embodiment can be formed more efficiently.

<Process B>

In the process B in the coating surface processing method of the present embodiment, any method may be used as the method for carrying out the plasma processing on the surface of the coating formed in the process A as long as plasma is generated in the vicinity of the base body so that a surface processing is carried out by allowing the plasma to approach the surface of the coating while reduction of the coating is suppressed, and the minute protrusions and recesses generated on the coating that is formed on the inner wall surfaces of the fine holes or grooves in the base body can be flattened.

The film-forming method is preferably the sputtering method or the CVD method in the process A since the process B after the process A can be advanced in the same film-forming apparatus.

The plasma used in the process B is generated by ionizing an inert gas in the vacuum chamber provided with a cathode and an anode. Examples of the apparatus that can be used provided with such a vacuum chamber include the sputtering apparatus 1 as shown in FIG. 1.

In the sputtering apparatus 1, the target 5 is disposed in the vacuum chamber 10 so as to be substantially in parallel with and opposite to the base body 7. An intermediate region between the base body 7 and the target 5 is indicated by the dotted line L in FIG. 1.

In the coating surface processing method of the present embodiment, it is preferable that a first plasma, which is used in the process A, be generated on the target 5 side of the intermediate region, and a second plasma, which is used in the process B, be generated on the base body 7 side of the intermediate region.

The first plasma is generated on the target 5 side of the intermediate region so that the second plasma is relatively located in the vicinity of the base body 7, it becomes easy for the first plasma to sputter the target 5, thus the sputtering efficiency in the process A is increased, and a coating can be formed efficiently on the entire surface of the to-be-filmed surface of the base body 7.

The second plasma is generated on the base body 7 side of the intermediate region so that the second plasma is relatively located in the vicinity of the base body 7, thus the plasma processing can be carried out more efficiently on the base body 7.

Here, the space in the vacuum chamber 10 is divided into 5 sections from the base body 7 to the target 5, and the sections are termed a first area, a second area, a third area, a fourth area, and a fifth area in the order from the base body 7. The intermediate region is included in the third area.

The first plasma is more preferably generated in the fourth or fifth area, and still more preferably generated in the fifth area from the viewpoint of increasing the sputtering efficiency in the process A.

The second plasma is more preferably generated in the first or second area, and still more preferably generated in the second area from the viewpoint of increasing the flattening efficiency of the plasma processing in the process B. In a case in which the second plasma is generated in the first area, there is a concern that the coating formed on the base body 7 may be reduced, which is also dependent on the plasma density or the duration of the plasma processing.

The locations of the first plasma and the second plasma are specified by the areas to which the centers of the respective plasma belong. Even in a case in which the plasma is distributed over a plurality of areas, the location of the plasma is specified by the area to which the center of the plasma belongs.

In a case in which the second plasma is generated on the base body 7 side of the intermediate region as described above, the second plasma is preferably distributed so that the plasma processing is carried out on the entire area of the coating formed on the base body since the effect of the present embodiment is excellent. Distributing the plasma in the above manner enables the plasma processing to be sufficiently carried out not only on the coating in the fine holes or grooves located in the central portion of the base body 7 but also on the coating in the fine holes or grooves located on the end portion side of the base body 7.

Here, the distribution range of the second plasma refers to a range in which the second plasma is present at a plasma density large enough to flatten the minute protrusions and recesses generated on the coating that is formed on the inner wall surfaces of the fine holes or grooves in the base body 7 by the plasma processing for a predetermined duration.

In addition, in a case in which the first plasma is generated on the target 5 side of the intermediate region, and the second plasma is generated on the base body 7 side of the intermediate region as described above, it is preferable to distribute the second plasma in a wider region than the first plasma since the effect of the present embodiment is excellent.

The range in which the first plasma is distributed refers to a range in which the first plasma is present at a plasma density large enough to form the coating on the base body 7 by sputtering for a predetermined duration.

In a case in which the minute protrusions and recesses generated on the coating that is formed on the inner wall surfaces of the fine holes or grooves in the base body 7 are flattened using the sputtering apparatus 1, the following conditions of the plasma processing are preferred since the minute protrusions and recesses can be efficiently flattened by the coating surface processing method of the present embodiment.

The direct current power applied to the target 5 (cathode power) is preferably 0 kW to 9 kW, more preferably 0 kW to 6 kW, and still more preferably 0 kW to 3 kW.

The gas pressure at which time the second plasma is generated (the pressure inside the vacuum chamber 10) is preferably 1.0 Pa to 18 Pa, more preferably 4.0 Pa to 15 Pa, and still more preferably 8.0 Pa to 12 Pa.

The high-frequency power applied to the base body 7 by the high-frequency power supply 13 (stage high-frequency power) is preferably 150 W to 650 W, more preferably 200 W to 500 W, and still more preferably 250 W to 350 W.

The frequency applied to the base body 7 by the high-frequency power supply 13 is preferably 1.0 MHz to 13.56 MHz since the minute protrusions and recesses can be efficiently flattened by the coating surface processing method of the present embodiment.

A preferred combination of the respective ranges of the cathode power, the pressure inside the vacuum chamber 10, and the stage high-frequency power is that the cathode power is in a range of 0 kW to 9 kW, the pressure inside the vacuum chamber 10 is in a range of 1.0 Pa to 18 Pa, and the stage high-frequency is in a range of 150 W to 650 W.

A more preferred combination of the respective ranges of the cathode power, the pressure inside the vacuum chamber 10, and the stage high-frequency power is that the cathode power is in a range of 0 kW to 6 kW, the pressure inside the vacuum chamber 10 is in a range of 4.0 Pa to 15 Pa, and the stage high-frequency is in a range of 200 W to 500 W.

A still more preferred combination of the respective ranges of the cathode power, the pressure inside the vacuum chamber 10, and the stage high-frequency power is that the cathode power is in a range of 0 kW to 3 kW, the pressure inside the vacuum chamber 10 is in a range of 8.0 Pa to 12 Pa, and the stage high-frequency is in a range of 250 W to 350 W.

With the above combination, it is possible to generate the second plasma having a plasma density appropriate for the coating surface processing method of the present embodiment relatively in the vicinity of the base body 7, and therefore the minute protrusions and recesses can be more efficiently flattened.

In a case in which the minute protrusions and recesses generated on the coating that is formed on the inner wall surfaces of the fine holes or grooves in the base body 7 are flattened using the sputtering apparatus 1, the following is more preferred since the effect of the present embodiment is superior.

In a case in which the direct current powers Cp applied to the target are indicated by Cp(A) and Cp(B) in the processes A and B, the gas pressures P at which the plasma is generated in the processes A and B are indicated by P(A) and P(B), and the high-frequency powers applied to the base body in the processes A and B are indicated by Sp(A) and Sp(B), it is more preferable that the following formulae (1), (2), and (3) be satisfied.

Cp(A)>Cp(B) (1)

P(A)<P(B) (2)

Sp(A)<Sp(B) (3)

That is, it is more preferable to apply a lower direct current power (cathode power) to the target 5 in the process B than in the process A, increase the gas pressure at which the plasma is generated (the pressure inside the vacuum chamber 10) in the process B more than in the process A, and apply a higher high-frequency power (stage high-frequency power) to the base body 7 in the process B than in the process A.

Specifically, the preferred combination of the respective ranges of the cathode power, the pressure inside the vacuum chamber 10, and the stage high-frequency power in the process A and the preferred combination of the respective ranges of the cathode power, the pressure inside the vacuum chamber 10, and the stage high-frequency power in the process B are preferably combined.

In addition, the more preferred combination of the respective ranges of the cathode power, the pressure inside the vacuum chamber 10, and the stage high-frequency power in the process A and the more preferred combination of the respective ranges of the cathode power, the pressure inside the vacuum chamber 10, and the stage high-frequency power in the process B are more preferably combined.

Furthermore, the still more preferred combination of the respective ranges of the cathode power, the pressure inside the vacuum chamber 10, and the stage high-frequency power in the process A and the still more preferred combination of the respective ranges of the cathode power, the pressure inside the vacuum chamber 10, and the stage high-frequency power in the process B are still more preferably combined.

With the above combination, it is possible to generate the second plasma having a plasma density appropriate for the coating surface processing method of the present embodiment relatively in the vicinity of the base body 7, and therefore the minute protrusions and recesses can be more efficiently flattened.

The base body temperature during the plasma processing in the process B is preferably −50° C. to 550° C., more preferably 25° C. to 400° C., and still more preferably 25° C. to 300° C. since the effect of the present embodiment is excellent. In a case in which the base body temperature is desired to be decreased lower than the lower limit value of the above range, a cooling apparatus may be provided at a base body holder. When the base body temperature is in the above range, it is easy to adjust the base body temperature, and the coating formed on the inner wall surfaces of the fine holes or grooves can be efficiently flattened through the plasma processing.

While being dependent on the degree of the minute protrusions and recesses in the coating on the inner wall surfaces as well, the duration of the plasma processing in the process B is preferably 3.0 seconds to 60 seconds, more preferably 3.0 seconds to 40 seconds, and still more preferably 3.0 seconds to 20 seconds.

When the duration of the plasma processing is the lower limit value or more, the coating can be sufficiently flattened, and, when the duration of the plasma processing is the upper limit value or less, the coating can be flattened while reduction of the coating is suppressed.

Inert gas used in the well-known sputtering methods can be applied as the inert gas in the process B, and examples thereof include argon (Ar), krypton (Kr), helium (He), and the like. In a case in which the coating formed on the base body is composed of copper, Ar or Kr is preferred, and Ar is more preferred since the coating can be efficiently flattened.

Next, an example of the coating surface processing apparatus of the present embodiment will be described using the sputtering apparatus 1 as shown in FIG. 1.

The sputtering apparatus 1 as shown in FIG. 1 has a device a for controlling the direct current power applied to the target 5 which is connected to the direct current power supply 9 to be lower in the process B than in the process A. For example, an external apparatus that controls the direct current power supply 9 may be appropriately installed as the device α.

In addition, the sputtering apparatus 1 as shown in FIG. 1 has a device β for controlling the pressure inside the vacuum chamber 10 at which the plasma is generated to be higher in the process B than in the process A. For example, an external apparatus that controls the vacuum pump connected to the vacuum exhaust opening 3 may be appropriately installed as the device β.

Furthermore, the sputtering apparatus 1 as shown in FIG. 1 has a device γ for controlling the high-frequency power that is applied to the base body 7 by the base body electrode 6 to be larger in the process B than in the process A. For example, an external apparatus that controls the high-frequency power supply 13 connected to the base body electrode 6 may be appropriately installed as the device γ.

### EXAMPLES

Next, the present embodiment will be described in detail using examples, but the invention is not limited to the examples.

In Examples 1 to 3, the process A and the process B were carried out using the sputtering apparatus 1 as shown in FIG. 1. Meanwhile, a copper target was used as the target 5.

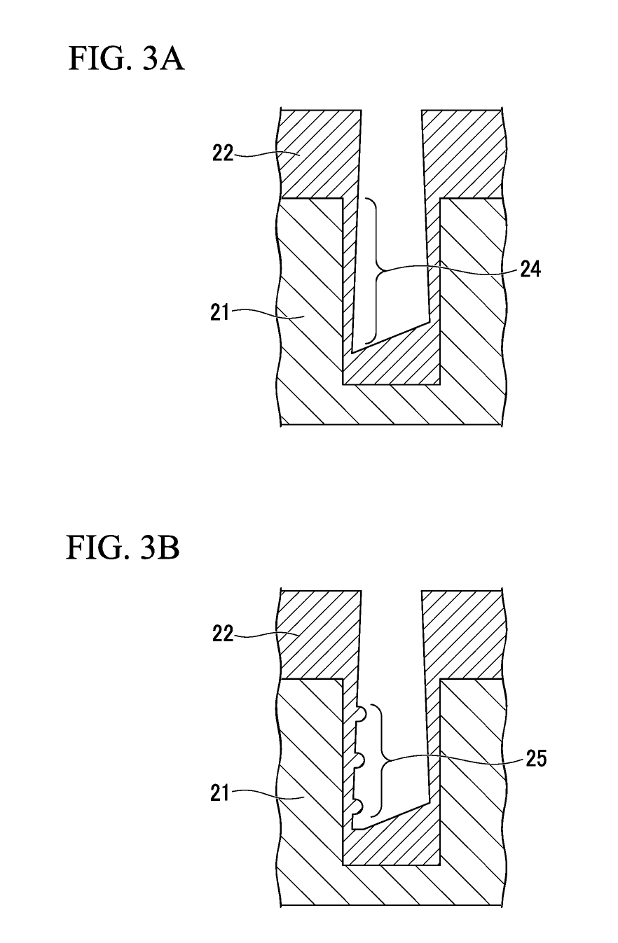

On the to-be-filmed surface, a coating 22 composed of copper was formed on a silicon wafer 21 on which a plurality of fine grooves (trench) having an opening size of 50 nm and an aspect ratio of 3.7 were formed using the sputtering apparatus 1 as shown in FIG. 1 (refer to FIG. 2). An approximately 8-nm-thick coating 23 was formed on the inner wall surfaces of the fine grooves, and, particularly, a plurality of protrusions and recesses having the size of approximately 6 nm were generated on the inner wall surface of the coating 23 on the inner side (on the central side of the silicon wafer 21).

The direct current power (cathode power) applied to the target 5, the gas pressure at which the plasma was generated (pressure inside the vacuum chamber 10), the high-frequency power applied to the silicon wafer 21 (stage high-frequency power), and the processing duration, which were the sputtering conditions in the process A, are shown in Table 1. In addition, the frequency of the high-frequency power supply 13 was 1.0 MHz to 13.56 MHz, and Ar was used as the inert gas. The first plasma generated under the conditions was generated in the fifth area on the copper target 5 side from the intermediate region that is indicated by the dotted line L in the vacuum chamber 10.

TABLE 1

| | PRESSURE | STAGE HIGH- | |
|---|---|---|---|
| CATHODE | INSIDE | FREQUENCY | PROCESSING |
| POWER | THE VACUUM | POWER | DURATION |
| (kW) | CHAMBER (Pa) | (W) | (seconds) |
| 15.0 | 0.08 | 50 | 30.0 |

### Examples 1 to 3

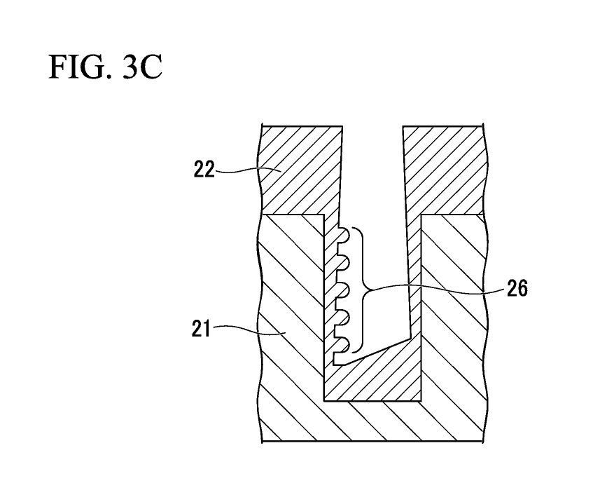

Next, the plasma-generating conditions were set as shown in Table 2, and different plasma processings were carried out on the surface of the coating 22 that was formed on the silicon wafer 21 and composed of copper, whereby the coating 23 on the inner wall surfaces of the fine grooves was flattened. The results are shown in Table 2 and FIGS. 3A to 3C.

The direct current power (cathode power) applied to the copper target 5, the gas pressure at which the plasma was generated (pressure inside the vacuum chamber 10), the high-frequency power applied to the silicon wafer 21 (stage high-frequency power), and the processing duration, which were the plasma-generating conditions in the process B, are shown in Table 2. In addition, the frequency of the high-frequency power supply 13 was 1.0 MHz to 13.56 MHz, and Ar was used as the inert gas. The second plasma generated under the conditions was generated in the second area on the silicon wafer 21 side from the intermediate region that is indicated by the dotted line L in the vacuum chamber 10. In addition, the second plasma was distributed in a wider region than the first plasma.

TABLE 2

| | | PRESSURE | STAGE HIGH- | | |
|---|---|---|---|---|---|
| | CATHODE | INSIDE | FREQUENCY | PROCESSING | FLATTENING |
| | POWER | THE VACUUM | POWER | DURATION | OF THE |
| | (kW) | CHAMBER (Pa) | (H) | (seconds) | INNER WALL |
| EXAMPLE 1 | 0.0 | 10.0 | 300 | 30.0 | ⊚ |
| EXAMPLE 2 | 0.0 | 2.0 | 300 | 30.0 | ◯ |
| EXAMPLE 3 | 0.0 | 20.0 | 300 | 30.0 | Δ |

In Example 1, the coating 23 before the plasma processing became a smoothly flattened coating 24 by the plasma processing (refer to FIG. 3A). In Example 2, the coating 23 before the plasma processing became a coating 25 flattened by the plasma processing (refer to FIG. 3B), and the sizes of the protrusions and recesses were decreased to half or less. In Example 3, the coating 23 before the plasma processing was slightly flattened by the plasma processing, but the effect thereof was restrictive, and the sizes of the protrusions and recesses were barely changed before and after the plasma processing (refer to FIG. 3C).

### DESCRIPTION OF THE REFERENCE SYMBOLS

1 . . . SPUTTERING APPARATUS

2 . . . GAS INTRODUCTION OPENING

3 . . . VACUUM EXHAUST OPENING

4 . . . CATHODE ELECTRODE

5 . . . TARGET

6 . . . BASE BODY ELECTRODE

7 . . . BASE BODY

8 . . . MAGNETIC CIRCUIT

9 . . . DIRECT CURRENT POWER SUPPLY

10 . . . VACUUM CHAMBER

11 . . . HEATER

11a . . . INSULATING PORTION

13 . . . HIGH-FREQUENCY POWER SUPPLY

21 . . . BASE BODY (SILICON WAFER)

22 . . . COATING COMPOSED OF COPPER

23 to 26 . . . COATING ON INNER WALL SURFACE OF FINE GROOVE

What is claimed is:

1. A coating surface processing method, comprising:
forming a coating on an entire surface of a base body, the base body having fine holes or fine grooves formed on a to-be-filmed surface thereof and the entire surface including inner wall surfaces and inner bottom surfaces of the holes or the grooves of the base body; and
flattening the coating formed on the inner wall surfaces of the holes or the grooves by carrying out a plasma processing on the surface of the coating.

2. The coating surface processing method according to claim 1, wherein the coating is formed on the base body by a sputtering method.

3. The coating surface processing method according to claim 2,
wherein a vacuum chamber in which the target is disposed so as to face the base body is used in the sputtering method,
first plasma is generated at a location near the target when the coating is formed on the base body, and
second plasma is generated at a location near the base body when the coating is flattened.

4. The coating surface processing method according to claim 3, wherein the second plasma is distributed so that the plasma processing is carried out on the entire areas of the coating formed on the base body.

5. The coating surface processing method according to claim 2,
wherein, in a case in which
a direct current power applied to the target is indicated by Cp(A),
when the coating is formed on the base body,
a direct current power applied to the target is indicated by Cp(B),
when the coating is flattened,
a gas pressure at which the plasma is generated is indicated by P(A),
when the coating is formed on the base body,
a gas pressure at which the plasma is generated is indicated by P(B),
when the coating is flattened,
a high-frequency power applied to the base body is indicated by Sp(A),
when the coating is formed on the base body, and
a high-frequency power applied to the base body is indicated by Sp(B),
when the coating is flattened,
the following formulae (1), (2), and (3) are satisfied.
Cp(A)>Cp(B) (1)
P(A)<P(B) (2)
Sp(A)<Sp(B) (3)

6. A coating surface processing apparatus, wherein the coating surface processing method according to claim 1 is employed.
